(19) United States
(12) Patent Application Publication
(10) Pub. No.: US 2025/0321380 A1
(43) Pub. Date: Oct. 16, 2025

(54) ELECTRONIC DEVICE

(71) Applicant: Advanced Semiconductor Engineering, Inc., Kaohsiung (TW)

(72) Inventors: Chang Yi WU, Kaohsiung (TW); Chih-Hong LIN, Kaohsiung (TW); Jenchun CHEN, Kaohsiung (TW); Ya-Wen LIAO, Kaohsiung (TW)

(73) Assignee: Advanced Semiconductor Engineering, Inc., Kaohsiung (TW)

(21) Appl. No.: 18/633,940

(22) Filed: Apr. 12, 2024

(51) Int. Cl. G02B 6/30; H01L 23/00; H01L 25/18

(52) U.S. Cl. CPC G02B 6/30; H01L 24/32; H01L 24/13; H01L 24/16; H01L 24/17; H01L 24/73; H01L 24/83; H01L 25/18; H01L 2224/13139; H01L 2224/13144; H01L 2224/13147; H01L 2224/16145; H01L 2224/16225; H01L 2224/17181; H01L 2224/32052; H01L 2224/32057; H01L 2224/32225; H01L 2224/73203; H01L 2224/73253; H01L 2224/8309; H01L 2224/831; H01L 2224/83201

(57) ABSTRACT

An electronic device is provided. The electronic device includes a photonic component, a plurality of optical elements, a connection layer, and a cover. The photonic component defines a predetermined region. The optical elements are disposed at the predetermined region and configured to optically couple with the photonic component. The connection layer is connected to the photonic component and the optical elements. The cover is configured to protect the optical elements and configured to vent.

### BACKGROUND

### 1. Technical Field

The present disclosure relates generally to an electronic device.

### 2. Description of the Related Art

Currently, optical coupling between a photonic component and optical fibers in a package may be achieved by disposing the optical fibers in grooves of the photonic component followed by dispensing a gel to adhere the optical fibers to the photonic component. However, bubbles may be formed in the gel, which may adversely affect the optical coupling between the photonic component and the optical fibers.

### SUMMARY

In one or more arrangements, an electronic device includes a photonic component, a plurality of optical elements, a connection layer, and a cover. The photonic component defines a predetermined region. The optical elements are disposed at the predetermined region and configured to optically couple with the photonic component. The connection layer is connected to the photonic component and the optical elements. The cover is configured to protect the optical elements and configured to vent.

In one or more arrangements, an electronic device includes a photonic component, an optical structure, and a cover. The optical structure and the photonic component collectively define a first optically coupling region and a second optically coupling region. The cover has a first opening over the first optically coupling region and a second opening spaced apart from the first opening and over the second optically coupling region.

In one or more arrangements, an electronic device includes a photonic component, a plurality of optical elements, a connection layer, and a cover. The optical elements are configured to optically couple with the photonic component. The connection layer is configured to provide an optical communication between the optical elements and the photonic component. The cover has an opening exposing a portion of the connection layer.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a top view of an electronic device in accordance with some arrangements of the present disclosure.

FIG. 1B is a cross-section of an electronic device in accordance with some arrangements of the present disclosure.

FIG. 1C is a cross-section of an electronic device in accordance with some arrangements of the present disclosure.

FIG. 1D is a cross-section of an electronic device in accordance with some arrangements of the present disclosure.

FIG. 1E is a cross-section of an electronic device in accordance with some arrangements of the present disclosure.

FIG. 1F is a top view of a portion of an electronic device in accordance with some arrangements of the present disclosure.

FIG. 1G is a top view of a portion of an electronic device in accordance with some arrangements of the present disclosure.

FIG. 2A is a top view of a portion of an electronic device in accordance with some arrangements of the present disclosure.

FIG. 2B is a top view of a portion of an electronic device in accordance with some arrangements of the present disclosure.

FIG. 2C is a top view of a portion of an electronic device in accordance with some arrangements of the present disclosure.

FIG. 2D is a top view of a portion of an electronic device in accordance with some arrangements of the present disclosure.

FIG. 3A is a top view of a portion of an electronic device in accordance with some arrangements of the present disclosure.

FIG. 3B is a top view of a portion of an electronic device in accordance with some arrangements of the present disclosure.

FIG. 4A is a top view of a portion of an electronic device in accordance with some arrangements of the present disclosure.

FIG. 4B is a top view of a portion of an electronic device in accordance with some arrangements of the present disclosure.

FIG. 4C is a top view of a portion of an electronic device in accordance with some arrangements of the present disclosure.

FIG. 5A is a cross-section of a portion of an electronic device in accordance with some arrangements of the present disclosure.

FIG. 5B is a cross-section of a portion of an electronic device in accordance with some arrangements of the present disclosure.

FIG. 6A is a cross-section of an electronic device in accordance with some arrangements of the present disclosure.

FIG. 6B is a cross-section of an electronic device in accordance with some arrangements of the present disclosure.

FIG. 7A, FIG. 7B, FIG. 7C, and FIG. 7D illustrate various stages of an exemplary method for manufacturing an electronic device in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

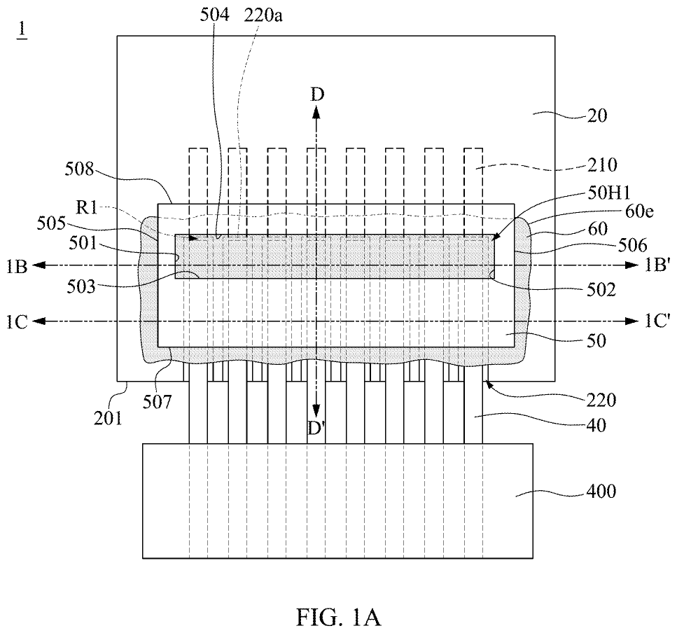

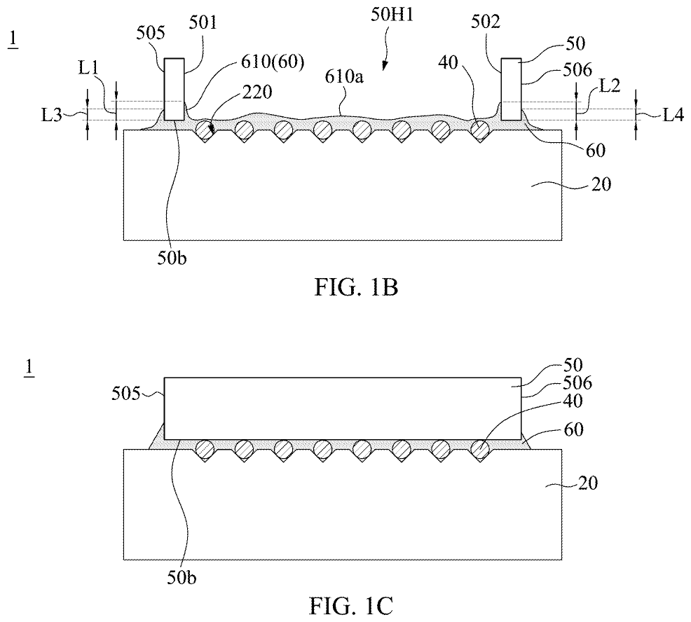

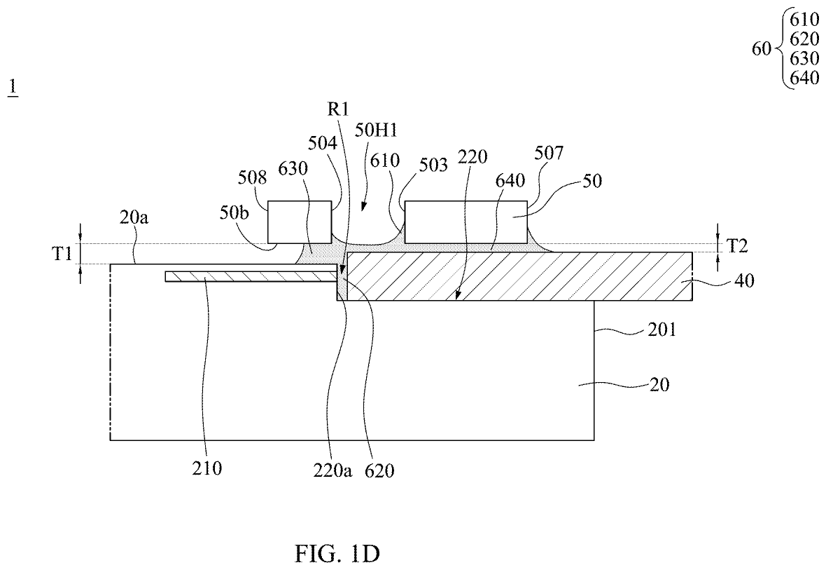

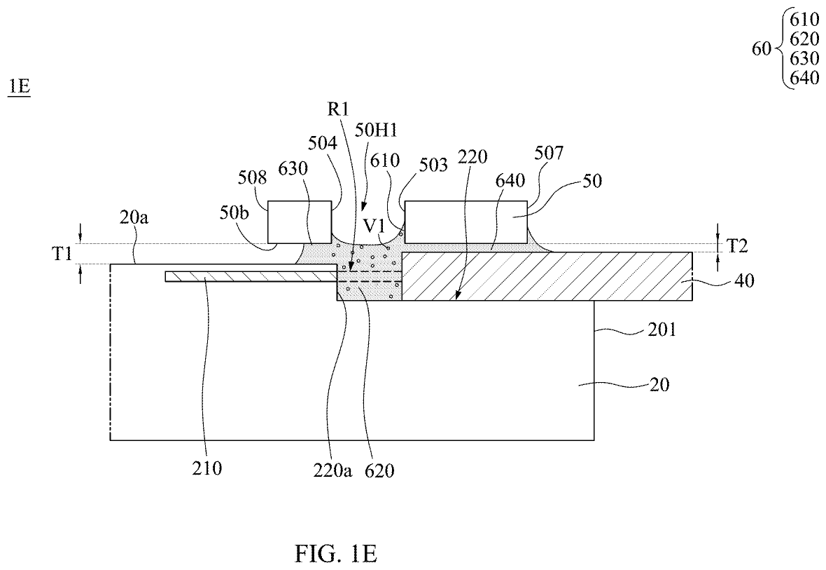

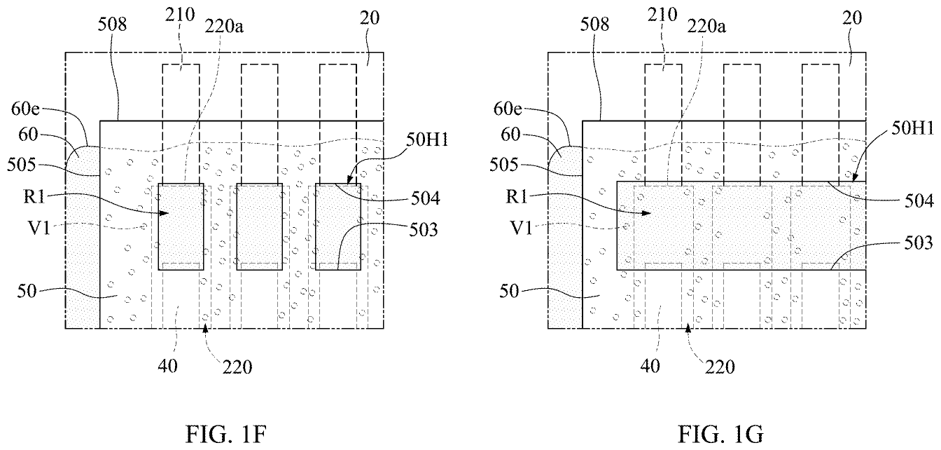

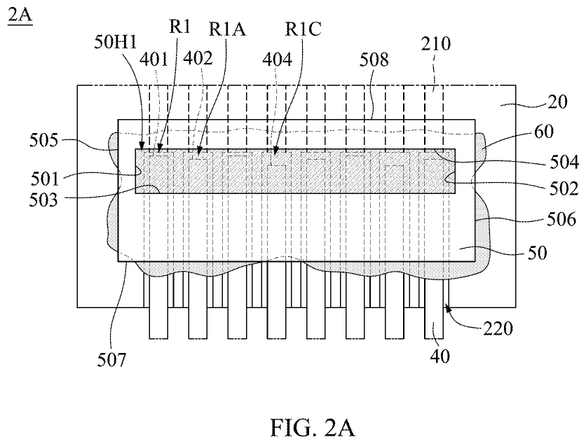

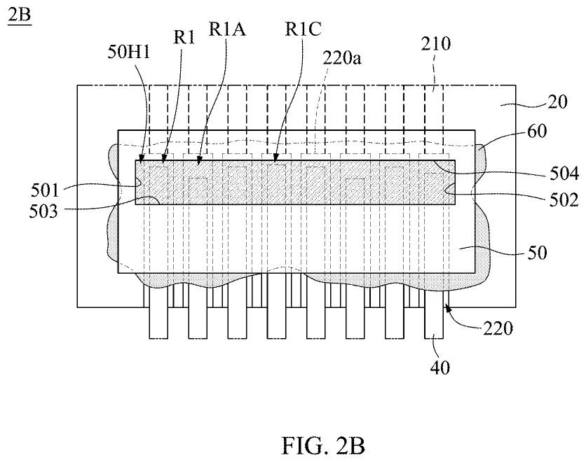

FIG. 1A is a top view of an electronic device 1 in accordance with some arrangements of the present disclosure. FIG. 1B is a cross-section of an electronic device 1 in accordance with some arrangements of the present disclosure. FIG. 1C is a cross-section of an electronic device 1 in accordance with some arrangements of the present disclosure. FIG. 1D is a cross-section of an electronic device 1 in accordance with some arrangements of the present disclosure. In some arrangements, FIG. 1B is a cross-section along a line 1B-1B′ in FIG. 1A, FIG. 1C is a cross-section along a line 1C-1C′ in FIG. 1A, and FIG. 1D is a cross-section along a line 1D-1D′ in FIG. 1A. The electronic device 1 may include a photonic component 20, an optical component 400, a cover 50 (also referred to as “a lid”), and a connection layer 60.

The photonic component 20 may include a plurality of waveguides 210 (also referred to as “optical waveguides” or “optical channels”) and a plurality of grooves 220 (also referred to as “trenches” or “recesses”). In some arrangements, the photonic component 20 defines a plurality of end surfaces 220a of the grooves 220. In some arrangements, the photonic component 20 is configured to provide a photoelectric conversion. In some arrangements, the photonic component 20 is configured to communicate optical signals (or modulated optical signals). For example, the photonic component 20 may be configured to transmit or receive optical signals. In some embodiments, the waveguides 210 of the photonic component 20 are configured to transmit optical signals (e.g., light), for example, received from a laser diode, an optical fiber, or an optical fiber array. In some arrangements, the waveguides 210 are exposed by the end surfaces 220a. In some arrangements, the waveguides 210 are exposed to the grooves 220. In some arrangements, the waveguides 210 may be formed of or include an optical waveguide material, e.g., a polymer material (e.g., a polymer waveguide), silicon nitride, silicon oxide, or other suitable materials. In some arrangements, the photonic component 20 includes a photonic integrated circuit (PIC) or a photonic die. In some embodiments, the photonic component 20 may further include a laser diode, a receiver, a photodetector, a photodiode, a semiconductor optical amplifier (SOA), a grating coupler, a fiber coupling structure, an optical modulator (e.g., Mach-Zehnder modulator or microring modulator), or a combination thereof. For example, the photonic component 20 may include a combination of photonic devices in a circuit and other active and passive optical devices on a single substrate to achieve a desired function.

The optical component 400 may include a plurality of optical elements 40 (also referred to as “fibers” or “optical fibers”). The optical elements 40 may collectively referred to as an optical structure. In some arrangements, the optical elements 40 are connected to the photonic component 20. In some arrangements, the optical elements 40 are configured to optically couple to the photonic component 20. The photonic component 20 may define a predetermined region, and the optical elements 40 may be disposed at the predetermined region. In some arrangements, the predetermined region of the photonic component 20 may be or include the grooves 220. In some arrangements, the grooves 220 of the photonic component 20 are configured to accommodate the optical elements 40. In some arrangements, each of the optical elements 40 is disposed in each of the grooves 220. In some arrangements, the waveguides 210 are exposed by the end surfaces 220a to optically couple to the optical elements 40. In some arrangements, an optically coupling region R1 is between each of the optical elements 40 and each of the waveguides 210. In some arrangements, the optical element 40 is spaced apart from the waveguide 210 by a gap or a space (e.g., the optically coupling region R1) within the groove 220. In some arrangements, the optical elements 40 cross over a surface 201 (also referred to as “a lateral surface”) of the photonic component 20.

The cover 50 may be disposed over the photonic component 20. The cover 50 may be configured to protect the optical elements 40 and configured to vent. In some arrangements, the cover 50 has an opening 50H1 over the optical elements 40. In some arrangements, a portion of at least one of the optical elements 40 is exposed by the opening 50H1 in a top view perspective. In some arrangements, the end surfaces 220a vertically overlap the opening 50H1. In some arrangements, the opening 50H1 vertically overlaps the optically coupling regions R1. In some arrangement, the optically coupling regions R1 are entirely under the opening 50H1. In some arrangements, the cover 50 has an inner sidewalls (e.g., surfaces 501, 502, 503, and 504) that defines the opening 50H1. In some arrangements, the cover 50 further has an outer sidewall (e.g., surfaces 505, 506, 507, and 508) that is opposite of the inner sidewall. In some arrangements, a surface 50b (also referred to as “a bottom surface”) of the cover 50 contacts the optical elements 40. In some arrangements, the optical element 40 is spaced apart from the waveguide 210 by a gap or a space (e.g., the optically coupling region R1), and the opening 50H1 has a first region over the gap or the space (e.g., the optically coupling region R1). In some arrangements, the opening 50H1 further has a second region different from the first region and over the waveguides 210 in a top view perspective.

The connection layer 60 may be disposed over a portion of the photonic component 20 and portions of the optical elements 40. In some arrangements, the connection layer 60 is connected to the photonic component 20 and the optical elements 40. In some arrangements, the connection layer 60 is between the cover 50 and portions of the optical elements 40. In some arrangements, the connection layer 60 covers the optical elements 40 and connects the cover 50 to the photonic component 20. In some arrangements, a portion of the connection layer 60 exceeds over the outer sidewall (e.g., the surfaces 505, 506, and 507) of the cover 50. In some arrangements, the connection layer 60 has an edge 60e having an irregular profile. In some arrangements, the connection layer 60 is made of or includes an adhesive layer. In some arrangements, the connection layer 60 is made of or includes an UV glue (also referred to as “an UV gel” or “an UV adhesive”). The connection layer 60 is made of or includes an UV curable adhesive material.

Referring to FIG. 1B, in some arrangements, the connection layer 60 includes a portion 610 (also referred to as “a protrusion”) disposed within the opening 50H1. In some arrangements, the portion 610 of the connection layer 60 is disposed within a portion of the opening 50H1. In some arrangements, the portion 610 of the connection layer 60 is locked into the opening 50H1 and configured to increase an adhesion between the cover 50 and the photonic component 20. In some arrangements, the portion 610 of the connection layer 60 contacts a portion of the inner sidewall of the cover 50. In some arrangements, the connection layer 60 extends over the inner sidewall by a length L1 and the outer sidewall by a length L3 different from the length L1 in a cross-sectional view. In some arrangements, the connection layer 60 extends over the inner sidewall by a length L2 and the outer sidewall by a length LA different from the length L2 in a cross-sectional view. In some arrangements, the inner sidewall includes the surface 501 and the surface 502 facing the surface 501 in a cross-sectional view, and the portion 610 (or the protrusion) of the connection layer 60 extends over the surface 501 by the length L1 and the surface 502 by the length L2 different from the length L1. In some arrangements, an elevation of a surface 610a (also referred to as “a top surface”) of the portion 610 (or the protrusion) of the connection layer 60 is higher than an elevation of a surface 50b (also referred to as “a bottom surface”) of the cover 50 with respect to a surface 20a (also referred to as “a top surface”) of the photonic component 20. In some arrangements, the surface 610a of the portion 610 of the connection layer 60 includes a curve surface or a wavy surface. The surface 610a includes a plurality of recessed regions and a plurality of protruded regions.

Referring to FIG. 1D, in some arrangements, the connection layer 60 is partially disposed in the opening 50H1. In some arrangements, the connection layer 60 is partially disposed in the opening 50H1 and contacting inner side surfaces (e.g., the surfaces 503 and 504) of the cover 50 that are exposed to the opening 50H1. In some arrangements, the connection layer 60 (of the portion 610 of the connection layer 60) further includes a first portion contacting the surface 503 and a second portion contacting the surface 504, and a height of the first portion is different from a height of the second portion.

Referring to FIG. 1D, in some arrangements, the connection layer 60 further includes portions 620, 630, and 640. In some arrangements, the portion 620 (also referred to as “a protrusion”) extends between the optical elements 40 and the photonic component 20. In some arrangements, the portion 620 contacts the optical elements 40 and the photonic component 20. In some arrangements, the portion 620 overlaps the optically coupling region R1. In some arrangements, the portion 620 is partially disposed in the optically coupling region R1. In some arrangements, the connection layer 60 (or the portion 620) is configured to provide an optical communication between the optical elements 40 and the photonic component 20. In some arrangements, the portion 630 (also referred to as “an extension”) is between the bottom surface (e.g., the surface 50b) of the cover 50 and the top surface (e.g., the surface 20a of the photonic component 20. In some arrangements, the portion 640 (also referred to as “an extension”) is between the bottom surface (e.g., the surface 50b) of the cover 50 and a top surface (e.g., a surface 40a) of the optical elements 40. In some arrangements, the portion 640 further contacts a portion of an outer sidewall (e.g., the surface 507) of the cover 50. In some arrangements, a thickness T1 of the portion 630 is greater than a thickness T2 of the portion 640.

In some arrangements, the opening 50H1 of the cover 50 is in communication with air and configured to vent. In some arrangements, the opening 50H1 of the cover 50 is in communication with air and configured to de-gas. The opening 50H1 of the cover 50 may be configured to vent from the predetermined region of the photonic component 20 to outside of the predetermined region. In some arrangements, the opening 50H1 exposes a portion of the connection layer 60. In some arrangements, the opening 50H1 of the cover 50 is configured to vent air or air bubbles from the connection layer 60 toward outside of the cover 50. In some arrangements, the opening 50H1 of the cover 50 is configured to vent air or air bubbles generated in the optically coupling region R1 toward outside of the connection layer 60.

After the optical elements 40 are disposed in the grooves 220 of the photonic component 20 to passively aligned with the waveguides 210 of the photonic component 20, an adhesive material may be dispensed onto the optical elements 40 to adhere the optical elements 40 to the photonic component 20, and then the cover 50 may be disposed over the adhesive material followed by curing the adhesive material to form the connection layer 60 to attach the cover 50 to the photonic component 20 and the optical elements 40. However, bubbles may be formed within the adhesive material in the grooves 220. The bubbles may stay in the optically coupling regions R1 to block the optical transmission between the optical elements 40 and the waveguides 210, and the bubbles may even move and thus push the optical elements 40 to shift in their positions which may cause the electronic device fail in function or cause optical coupling loss.

According to some arrangements of the present disclosure, with the design of the opening 50H1 of the cover 50, the bubbles formed in the adhesive material may vent toward outside of the adhesive material, such that bubbles remained in the connection layer 60 formed by curing the adhesive material can be significantly reduced. Therefore, the above issues of the electronic device failing in function or causing optical coupling loss can be mitigated or prevented, and the yield can be increased. Moreover, the structure and the manufacturing process of the cover 50 having an opening 50H1 are relatively simplified, complicated venting apparatus or structures (e.g., venting channels under the grooves of the photonic component or an additional structure including venting holes) can be omitted. Therefore, the processing tolerance can be increased, the cost can be reduced, and the UPH can be increased.

In addition, according to some arrangements of the present disclosure, the opening 50H1 of the cover 50 is directly above or vertically overlaps the optically coupling regions R1, such that the bubbles formed in the optically coupling regions R1 can quickly vent through a relatively short path toward outside of the adhesive material. Therefore, bubbles remained in the connection layer 60 at the optically coupling regions R1 can be reduced significantly, and thus the optical transmission performance between the optical elements 40 and the waveguides 210 can be significantly increased.

Furthermore, according to some arrangements of the present disclosure, the portion 610 of the connection layer 60 is partially formed within the opening 50H1, such that the adhesion interface or the contact area between the connection layer 60 and the cover 50 can be significantly increased. Therefore, the portion 610 can be locked into the opening 50H1 and thereby increase the adhesion between the cover 50 and the photonic component 20.

Moreover, according to some arrangements of the present disclosure, with the design of the relatively large opening 50H1, relatively large bubbles formed in the adhesive material with a relatively large viscosity can vent through the opening 50H1.

FIG. 1E is a cross-section of an electronic device 1E in accordance with some arrangements of the present disclosure.

In some arrangements, the cover 50 is configured to allow bubbles V1 to vent from the connection layer 60. In some arrangements, the optical elements 40 and the photonic component 20 collectively define one or more optically coupling region R1 without the bubbles V1 or free of the bubbles V1. In some arrangements, the connection layer 60 is partially disposed in the opening 50H1 of the cover 50. In some arrangements, a portion of the bubbles V1 is over the optically coupling region R1. In some arrangements, a portion of the bubbles V1 is under the optically coupling region R1.

FIG. 1F is a top view of a portion of an electronic device in accordance with some arrangements of the present disclosure. In some arrangements, FIG. 1F is a top view of a portion of the structure illustrated in FIG. 1E.

In some arrangements, the bubbles V1 may be generated or formed in the connection layer 60 and between the optical elements 40. In some arrangements, the bubbles V1 may be between the waveguides 210. In some arrangements, the bubbles V1 may be between the optically coupling regions R1 in a top view perspective. In some arrangements, the optically coupling regions R1 are substantially free of the bubbles V1.

FIG. 1G is a top view of a portion of an electronic device in accordance with some arrangements of the present disclosure. In some arrangements, FIG. 1G is a top view of a portion of the structure illustrated in FIG. 1E.

In some arrangements, the bubbles V1 may be generated or formed in the connection layer 60 and between the optical elements 40. In some arrangements, the bubbles V1 may be between the waveguides 210. In some arrangements, the bubbles V1 may be between the optically coupling regions R1 in a top view perspective. In some arrangements, the optically coupling regions R1 are substantially free of the bubbles V1. In some arrangements, with the design of the relatively large opening 50H1 that exposes portions of the connection layers 60 between the optically coupling regions R1 in a top view perspective, fewer bubbles V1 may be in the portions of the connection layer 60 between the optically coupling regions R1.

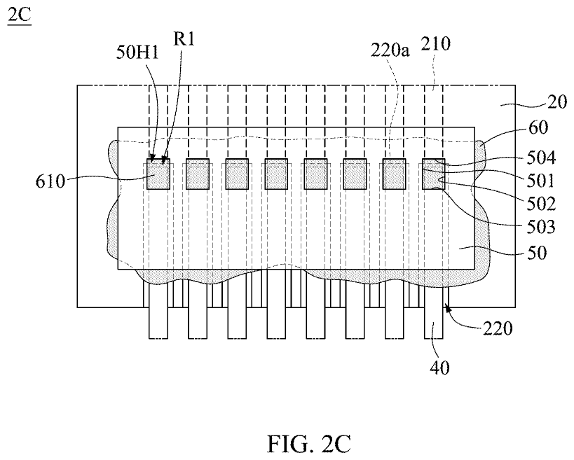

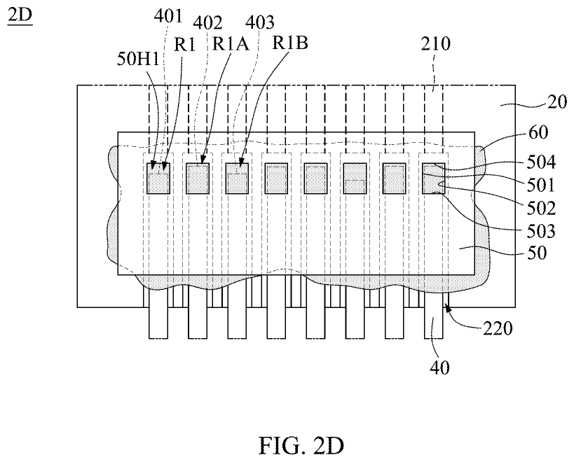

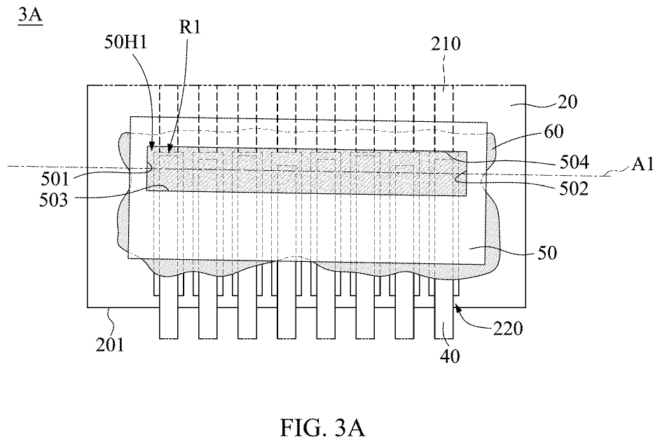

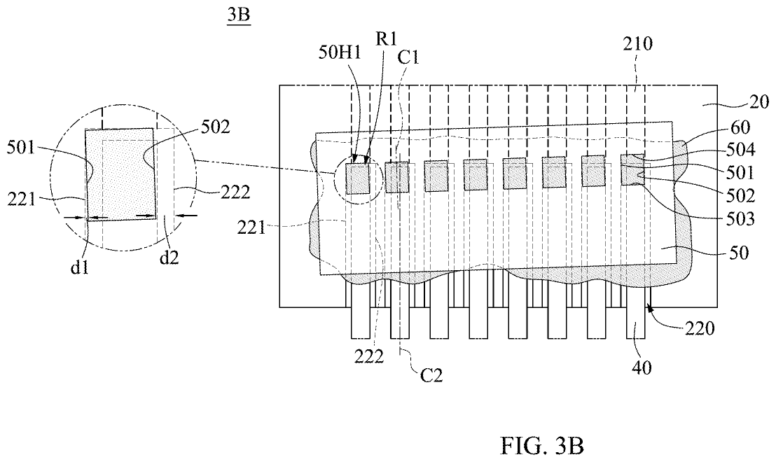

FIG. 2A is a top view of a portion of an electronic device 2A in accordance with some arrangements of the present disclosure. The electronic device 2A is similar to the electronic device 1 in FIG. 1A to FIG. 1D, and the differences therebetween are described as follows. In some arrangements, the electronic device 2A includes cross-sectional structures illustrated in FIG. 1B, FIG. 1C, and FIG. 1D.

In some arrangements, the optical elements 40 have optical interfaces facing the waveguides 210, and at least two of the optical interfaces are misaligned with each other. For example, an optical interface 401 of one of the optical elements 40 is misaligned with an optical interface 402 of another one of the optical elements 40. For example, optical interfaces 401, 402, and 404 of the optical elements 40 are misaligned.

In some arrangements, at least two of the optically coupling regions have different areas. For example, the optically coupling regions R1, R1A and R1C have different areas. In some arrangements, the optically coupling regions are entirely under the opening 50H1. In some arrangements, the optically coupling regions are entirely within a projection range of the opening 50H1 from a top view perspective. In some arrangements, the opening 50H1 of the cover 50 vertically overlaps the optically coupling regions R1, R1A and R1C by different areas.

FIG. 2B is a top view of a portion of an electronic device 2B in accordance with some arrangements of the present disclosure. The electronic device 2B is similar to the electronic device 1 in FIG. 1A to FIG. 1D, and the differences therebetween are described as follows. In some arrangements, the electronic device 2B includes cross-sectional structures illustrated in FIG. 1B, FIG. 1C, and FIG. 1D.

In some arrangements, the waveguides 210 are entirely covered by the cover 50. In some arrangements, the end surfaces 220a are entirely under the cover 50 without vertically overlapping the opening 50H1. In some arrangement, the optically coupling regions R1, R1A, and R1C are partially under the opening 50H1. In some arrangements, the optically coupling regions R1, R1A, and R1C vertically overlap the opening 50H1 by different areas.

FIG. 2C is a top view of a portion of an electronic device 2C in accordance with some arrangements of the present disclosure. The electronic device 2C is similar to the electronic device 1 in FIG. 1A to FIG. 1D, and the differences therebetween are described as follows. In some arrangements, the electronic device 2C includes cross-sectional structures illustrated in FIG. 1B and FIG. 1D.

In some arrangements, the cover 50 has a plurality of openings 50H1 over the optical elements 40. In some arrangements, two or more of the openings 50H1 are over two or more of the optical elements 40. In some arrangements, each of the openings 50H1 is over each of the optical elements 40. In some arrangements, each of the openings 50H1 vertically overlaps each of the optical elements 40.

In some arrangements, two or more of the openings 50H1 are respectively over two or more of the optically coupling regions R1 between the optical elements 40 and the waveguides 210. In some arrangements, each of the openings 50H1 is over each of the optically coupling regions R1. In some arrangements, each of the openings 50H1 vertically overlaps each of the optically coupling regions R1.

In some arrangements, two or more of the waveguides 210 vertically overlap two or more of the openings 50H1, respectively. In some arrangements, each of the waveguides 210 vertically overlaps each of the opening 50H1. In some arrangements, two or more of the openings 50H1 overlap two or more of the grooves 220 in a top view perspective. In some arrangements, each of the openings 50H1 overlaps each of the grooves 220 in a top view perspective. In some arrangements, two or more of the end surfaces 220a of the grooves 220 are respectively under the two or more of the openings 50H1 without being covered by the cover 50. In some arrangements, each of the end surfaces 220a of the grooves 220 is under each of the openings 50H1 without being covered by the cover 50.

In some arrangements, the connection layer 60 includes a plurality of portions 610 disposed within at least two of the openings 50H1. In some arrangements, each of the portions 610 of the connection layer 60 is disposed within each of the openings 50H1.

According to some arrangements of the present disclosure, with the design of the plurality of openings 50H1 each having a relatively small size, overflows of the adhesive material during manufacture can be mitigate or prevented effectively, and thus the connection layer 60 can be formed with nearly no bubbles therein while the overall structure of the connection layer 60 is integral without volume loss due to overflows of the adhesive material.

In addition, according to some arrangements of the present disclosure, small portions 610 of the connection layer 60 are partially formed within the openings 50H1, such that adhesion interfaces or contact areas between the connection layer 60 and the cover 50 can be significantly increased. Therefore, the portions 610 can be locked into the openings 50H1 and thereby increase the adhesion between the cover 50 and the photonic component 20.

FIG. 2D is a top view of a portion of an electronic device 2D in accordance with some arrangements of the present disclosure. The electronic device 2D is similar to the electronic device 1 in FIG. 1A to FIG. 1D, and the differences therebetween are described as follows. In some arrangements, the electronic device 2D includes cross-sectional structures illustrated in FIG. 1B and FIG. 1D.

In some arrangements, the openings 50H1 vertically overlap the optically coupling regions by different areas. For example, one of the openings 50H1 vertically overlaps the optically coupling region R1 by a first area, and another one of the openings 50H1 vertically overlaps the optically coupling region RIA by a second area different from the first area. In some arrangements, the openings 50H1 vertically overlap the optically coupling regions R1, R1A, ad RIB by different areas.

In some arrangements, each of the optical elements 40 may have an optical interface facing a respective one of the waveguides 210, and two or more of the optical interfaces are misaligned. In some arrangements, the optical elements 40 include a first fiber having an optical interface 401 and a second fiber having an optical interface 402 respectively under one of the openings 50H1, and the optical interface 401 is misaligned with the optical interface 402. In some arrangements, the optical interfaces 401, 402, and 403 of the optical elements 40 are misaligned.

The optical elements 40 may collectively referred to as an optical structure. In some arrangements, the optical structure and the photonic component 20 collectively define the optically coupling regions R1, R1A, and R1B. In some arrangements, the cover 50 includes a plurality of openings 50H1 spaced apart from each other and over the optically coupling regions R1, R1A, and RIB, respectively. In some arrangements, the photonic component 20 includes a plurality of waveguides 210, and the optical elements 40 (or the fibers) of the optical structure are configured to optically couple with the waveguides through the optical coupling regions R1, R1A, and RIB, respectively. In some arrangements, the connection layer 60 is disposed in the optical coupling regions R1, R1A, and R1B. In some arrangements, the connection layer 60 is further disposed between the optical elements 40 (or the fibers).

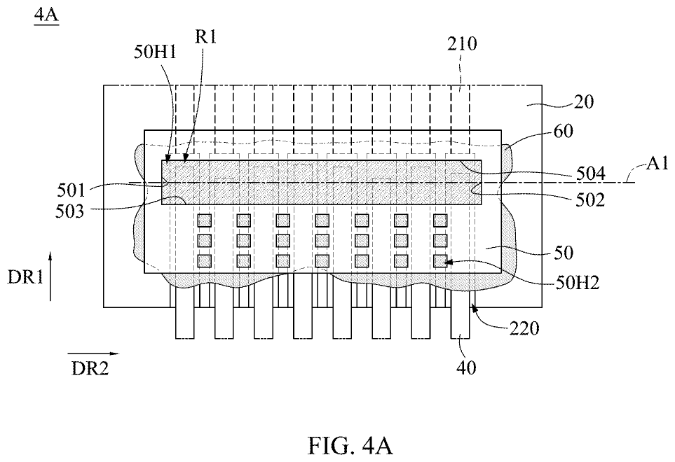

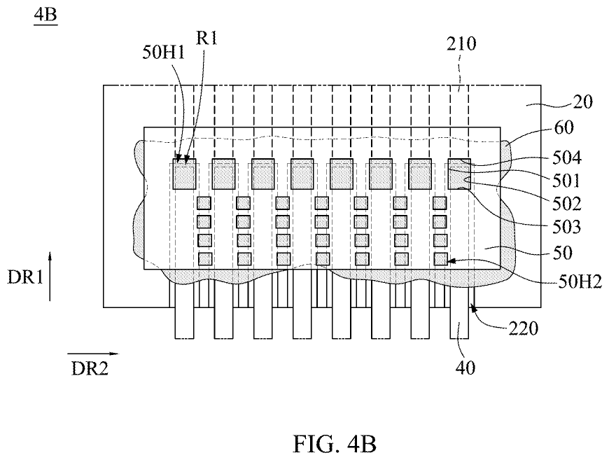

FIG. 3A is a top view of a portion of an electronic device 3A in accordance with some arrangements of the present disclosure. The electronic device 3A is similar to the electronic device 1 in FIG. 1A to FIG. 1D, and the differences therebetween are described as follows. In some arrangements, the electronic device 3A includes cross-sectional structures illustrated in FIG. 1B, FIG. 1C, and FIG. 1D.

In some arrangements, the cover 50 is rotatably or rotationally shifted with respect to the photonic component 20. In some arrangements, in a top view perspective, a longitudinal axis A1 of the opening 50H1 is non-parallel to a lateral surface (e.g., the surface 201) of the photonic component 20. In some arrangements, the surfaces 503 and 504 of the cover 50 are non-parallel to the surface 201 of the photonic component 20.

FIG. 3B is a top view of a portion of an electronic device 3B in accordance with some arrangements of the present disclosure. The electronic device 3B is similar to the electronic device 1 in FIG. 1A to FIG. 1D, and the differences therebetween are described as follows. In some arrangements, the electronic device 3B includes cross-sectional structures illustrated in FIG. 1B and FIG. 1D.

In some arrangements, the cover 50 is rotatably or rotationally shifted with respect to the photonic component 20. In some arrangements, the cover 50 is rotatably or rotationally shifted relative to the optical elements 40. In some arrangements, in a top view perspective, a center axis C1 of at least one of the openings 50H1 is misaligned with a center axis C2 of the optical element 40 disposed under the opening 50H1. In some arrangements, the cover 50 has an inner sidewall (e.g., the surface 501) defining the opening 50H1, and at least one of the optical elements 40 has a side surface extending substantially along and non-parallel to the inner sidewall (or the surface 501). In some arrangements, the cover 50 is translationally shifted with respect to the photonic component 20. In some arrangements, a distance d1 between the surface 501 and a lateral side 221 of the groove 220 is different from a distance d2 between the surface 502 and a lateral side 222 of the groove 220 in a top view perspective.

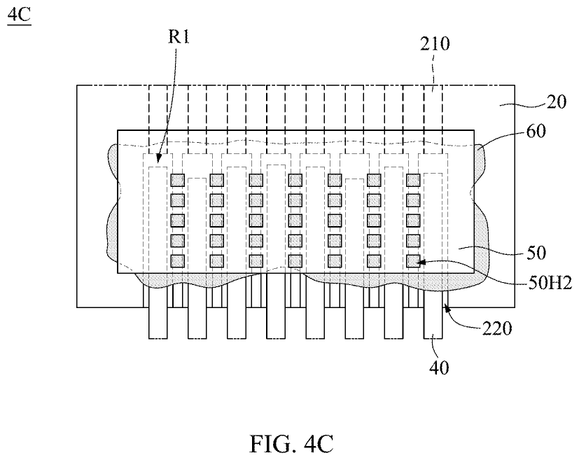

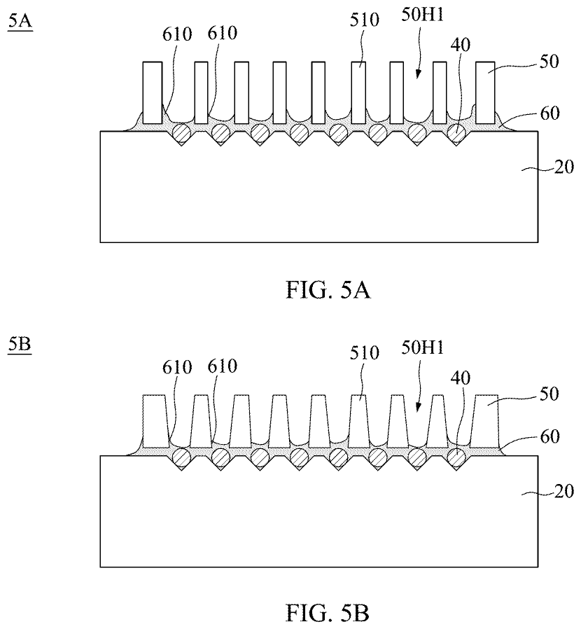

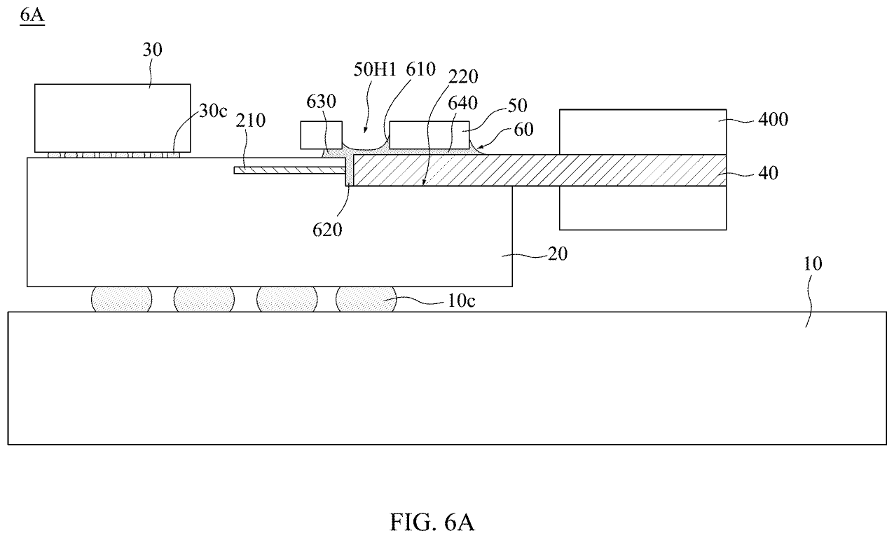

FIG. 4A is a top view of a portion of an electronic device 4A in accordance with some arrangements of the present disclosure. The electronic device 4A is similar to the electronic device 1 in FIG. 1A to FIG. 1D, and the differences therebetween are described as follows. In some arrangements, the electronic device 4A includes cross-sectional structures illustrated in FIG. 1B, FIG. 1C, and FIG. 1D.

In some arrangements, the cover 50 further has openings 50H2. In some arrangements, the openings 50H2 are free from vertically overlapping the optical elements 40. In some arrangements, the openings 50H2 vertically overlap regions between the optical elements 40. In some arrangements, the openings 50H2 are arranged along a direction DR1, and the longitudinal axis A1 of the opening 50H1 extends in a direction DR2 substantially perpendicular to the direction DR1.

In some arrangements, the photonic component includes a plurality of waveguides 210, and at least two of the waveguides 210 are optically coupled with and spaced apart from at least two of the optical elements 40 (or the fibers) by at least two different distances, respectively.

According to some arrangements of the present disclosure, with the design of the openings 50H2, extra bubbles generated in the adhesive material can further vent through the openings 50H2. Therefore, the bubbles can quickly vent through the openings 50H1 and 50H2, the remained bubbles in the connection layer 60 is further reduced significantly, which is advantageous to improving the optical transmission performance.

FIG. 4B is a top view of a portion of an electronic device 4B in accordance with some arrangements of the present disclosure. The electronic device 4B is similar to the electronic device 1 in FIG. 1A to FIG. 1D, and the differences therebetween are described as follows. In some arrangements, the electronic device 4B includes cross-sectional structures illustrated in FIG. 1B and FIG. 1D.

In some arrangements, the openings 50H2 are arranged along a direction DR1, and the openings 50H1 are arranged along the direction DR2 substantially perpendicular to the direction DR1. In some arrangements, the openings 50H2 are between the optical elements 40 (or the fibers) in a top view perspective.

FIG. 4C is a top view of a portion of an electronic device 4C in accordance with some arrangements of the present disclosure. The electronic device 4C is similar to the electronic device 4A in FIG. 4A, and the differences therebetween are described as follows.

In some arrangements, the cover 50 does not have the opening 50H1. In some arrangements, the cover 50 has openings 50H2. According to some arrangements of the present disclosure, with the design of the relatively small openings 50H2, relatively small bubbles formed in the adhesive material with a relatively small viscosity can vent through the openings 50H2, and the adhesive material can be blocked by cover 50 with the relatively small openings 50H2, such that the adhesive material can be prevented from overflowing outwards.

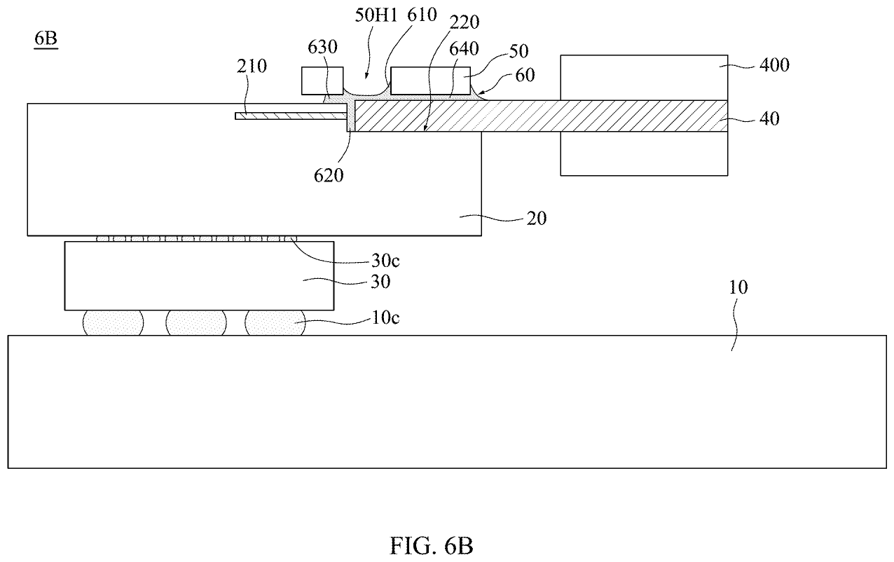

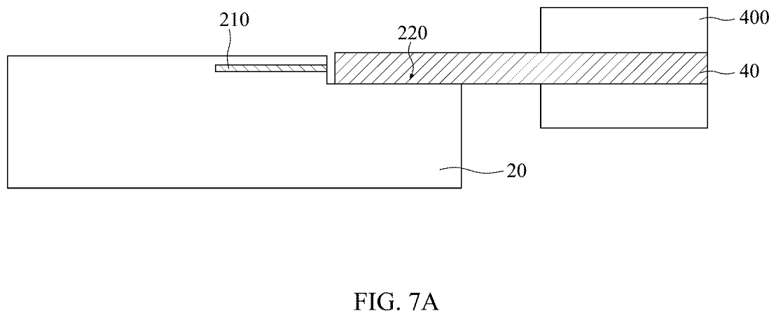

FIG. 5A is a cross-section of a portion of an electronic device 5A in accordance with some arrangements of the present disclosure. The electronic device 5A is similar to the electronic device 2C in FIG. 2C, the electronic device 2D in FIG. 2D, the electronic device 3B in FIG. 3B, or the electronic device 4B in FIG. 4B, and the differences therebetween are described as follows.

In some arrangements, the connection layer 60 includes a plurality of portions 610 disposed within at least two of the openings 50H1. In some arrangements, each of the portions 610 of the connection layer 60 is partially disposed within each of the openings 50H1. In some arrangements, two or more heights of the portions 610 in different openings 50H1 are different. In some arrangements, the openings 50H1 may be formed by an anisotropic dry etching operation (e.g., a RIE etching operation).

FIG. 5B is a cross-section of a portion of an electronic device 5B in accordance with some arrangements of the present disclosure. The electronic device 5B is similar to the electronic device 2C in FIG. 2C, the electronic device 2D in FIG. 2D, the electronic device 3B in FIG. 3B, or the electronic device 4B in FIG. 4B, and the differences therebetween are described as follows.

In some arrangements, the opening 50H1 has a tapered cross-sectional profile. In some arrangements, the opening 50H1 tapers toward the optical elements 40. In some arrangements, the opening 50H1 has a tapered shape. In some arrangements, the openings 50H1 may be formed by an isotropic wet etching operation.

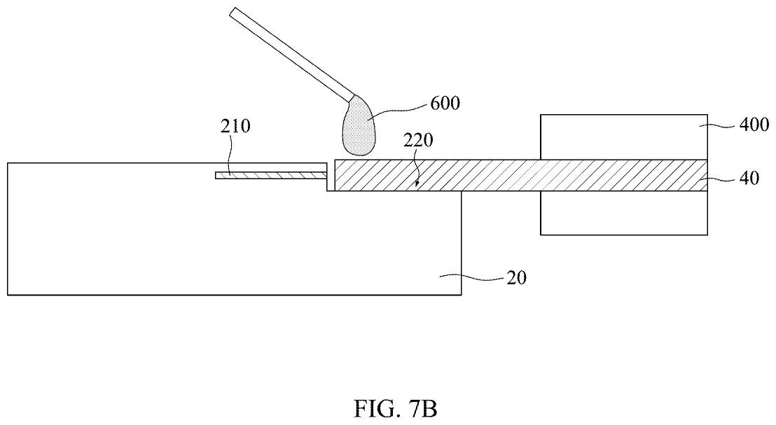

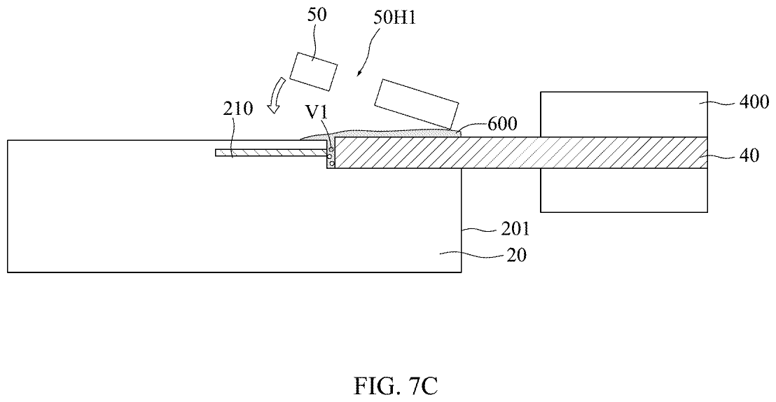

FIG. 6A is a cross-section of an electronic device 6A in accordance with some arrangements of the present disclosure. The electronic device 6A is similar to the electronic device 1 in FIG. 1A to FIG. 1D, and the differences therebetween are described as follows. In some arrangements, the electronic device 6A includes cross-sectional structures illustrated in FIG. 1B, FIG. 1C, and FIG. 1D.

In some arrangements, the electronic device 6A further includes a substrate 10, an electronic component 30, and connection elements 10c and 30c.

In some arrangements, the substrate 10 supports and electrically connects to the photonic component 20. In some arrangements, the photonic component 20 is electrically connected to the substrate 10 through the connection elements 10c. The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and-or a plurality of conductive vias. In some arrangements, the substrate 10 includes a ceramic material or a metal plate. In some arrangements, the substrate 10 may include such as an organic substrate or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of traces. In some embodiments, the connection elements 10c may be or include electrical contacts, which may include controlled collapse chip connection (C4) bumps, a ball grid array (BGA), or a land grid array (LGA).

In some arrangements, the electronic component 30 is disposed over the substrate 10 and electrically connected to the photonic component 20. In some arrangements, the electronic component 30 is electrically connected to the photonic component 20 through the connection elements 30c. In some arrangements, the electronic element 30 includes multiple devices configured to control modulation of optical signals received from the photonic component 20 and configured to amplify electrical signals, respectively. In some arrangements, the electronic component 30 includes an electronic integrated circuit (EIC) or an electronic die. The electronic component 30 may include a modulator driver (DRV), a trans-impedance amplifier (TIA), or a combination thereof. In some arrangements, the electronic element 30 may include one or more active devices, one or more passive circuit components, and electrically conductive paths interconnecting the active devices and the passive circuit components in electrical circuit relationships for performing a desired sub-circuit control function. In some arrangements, the connection elements 30c may be or include conductive bumps which may be or may include gold (Au), silver (Ag), copper (Cu), another metal, a solder alloy, or a combination of two or more thereof.

FIG. 6B is a cross-section of an electronic device 6B in accordance with some arrangements of the present disclosure. The electronic device 6B is similar to the electronic device 6A in FIG. 6A, and the differences therebetween are described as follows.

In some arrangements, the electronic component 30 is disposed between the photonic component 20 and the substrate 10. In some arrangements, the electronic component 30 is electrically connected to the photonic component 20 through the connection elements 30c. In some arrangements, the electronic component 30 is electrically connected to the substrate 10 through the connection elements 10c.

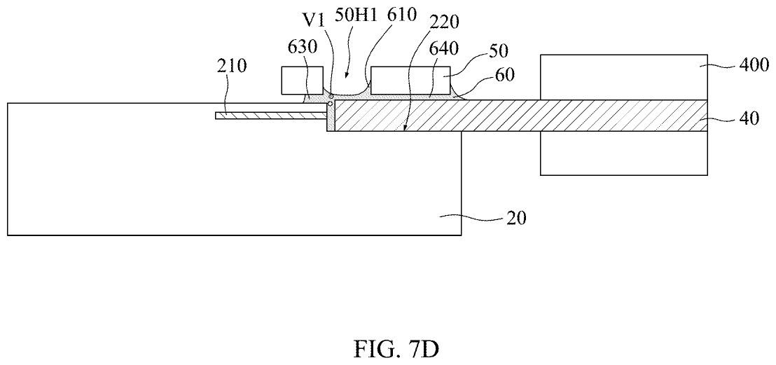

FIG. 7A, FIG. 7B, FIG. 7C, and FIG. 7D illustrate various stages of an exemplary method for manufacturing an electronic device 1 in accordance with some embodiments of the present disclosure.

Referring to FIG. 7A and FIG. 1A, a photonic component 20 including waveguides 210 and grooves 220 may be provided, and optical elements 40 of the optical component 400 may be disposed in the grooves 220. In some arrangements, the optical elements 40 are passively aligned with the waveguides 210 of the photonic component 20. In some arrangements, prior to the passive alignment operation, an active alignment operation may be performed between the optical elements 40 and the waveguides 210 to obtain predetermined positions for the passive alignment operations in a mass production process, and the passive alignment operation illustrated in FIG. 7A may be performed according to the predetermined positions obtained.

Referring to FIG. 7B and FIG. 1A, an adhesive material 600 may be dispensed onto the optical elements 40 in the grooves 220.

Referring to FIG. 7C and FIG. 1A, a cover 50 having one or more openings 50H1 (and optionally openings 50H2) may be disposed over the adhesive material 600 and the optical elements 40. In some arrangements, the cover 50 may be disposed by allowing one edge of the cover 50 to approach to the adhesive material 600 followed by lowering the other edge of the cover 50 gradually toward the adhesive material 600. In some arrangements, the cover 50 may apply force onto the adhesive material 600 from one end adjacent to the surface 201 toward the other end adjacent to the waveguides 210, such that bubbles V1 (or air bubbles) formed in the adhesive material 600 may be pressed and pushed to vent toward outside of the adhesive material 600.

Referring to FIG. 7D and FIG. 1A, a curing operation may be performed on the adhesive material 600 to form an connection layer 60 that attaches the cover 50 to the photonic component 20 and the optical elements 40. In some arrangements, the structure may be disposed in a vacuum oven and heated to allow the bubble to vent. In some arrangements, the bubbles V1 may continue to vent toward outside of the connection layer 60 during the curing operation through the opening 50H1. As such, the electronic device 1 illustrated in FIGS. 1A-1D may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a photonic component defining a predetermined region;
a plurality of optical elements disposed at the predetermined region and configured to optically couple with the photonic component;
a connection layer connected to the photonic component and the optical elements; and
a cover configured to protect the optical elements and configured to vent.

2. The electronic device as claimed in claim 1, wherein the cover has an opening configured to vent from the predetermined region to outside of the predetermined region.

3. The electronic device as claimed in claim 2, wherein a portion of at least one of the optical elements is exposed by the opening in a top view perspective.

4. The electronic device as claimed in claim 2, wherein the photonic component comprises a plurality of optical channels spaced apart from the optical elements by a gap, and the opening has a first region over the gap.

5. The electronic device as claimed in claim 4, wherein the opening has a second region different from the first region and over the optical channels in a top view perspective.

6. The electronic device as claimed in claim 1, wherein the cover is configured to allow bubbles to vent from the connection layer.

7. The electronic device as claimed in claim 6, wherein the optical elements and the photonic component collectively define an optically coupling region that is free of the bubbles.

8. The electronic device as claimed in claim 7, wherein the cover has an opening, and the connection layer is partially disposed in the opening.

9. The electronic device as claimed in claim 8, wherein a portion of the bubbles is over the optically coupling region.

10. The electronic device as claimed in claim 1, wherein the cover has an opening and a first inner side surface and a second inner side surface exposed to the opening, and the connection layer is partially disposed in the opening and contacting the first inner side surface and the second inner side surface.

11. The electronic device as claimed in claim 10, wherein in a cross-sectional view perspective, the connection layer comprises a first portion contacting the first inner side surface and a second portion contacting the second inner side surface, and a height of the first portion is different from a height of the second portion.

12. An electronic device, comprising:
a photonic component;
an optical structure, wherein the optical structure and the photonic component collectively define a first optically coupling region and a second optically coupling region; and
a cover having a first opening over the first optically coupling region and a second opening spaced apart from the first opening and over the second optically coupling region.

13. The electronic device as claimed in claim 12, wherein the photonic component comprises a first waveguide and a second waveguide, and the optical structure comprises a first fiber configured to optically couple with the first waveguide through the first optically coupling region and a second fiber configured to optically couple with the second waveguide through the second optically coupling region.

14. The electronic device as claimed in claim 13, further comprising a connection layer disposed in the first optically coupling region and the second optically coupling region.

15. The electronic device as claimed in claim 14, wherein the connection layer is further disposed between the first fiber and the second fiber.

16. The electronic device as claimed in claim 13, wherein the cover further has a third opening between the first fiber and the second fiber in a top view perspective.

17. An electronic device, comprising:
a photonic component;
a plurality of optical elements configured to optically couple with the photonic component;
a connection layer configured to provide an optical communication between the optical elements and the photonic component; and
a cover having an opening exposing a portion of the connection layer.

18. The electronic device as claimed in claim 17, wherein the photonic component comprises a plurality of waveguides, and at least two of the waveguides are optically coupled with and spaced apart from at least two of the optical elements by at least two different distances, respectively.

19. The electronic device as claimed in claim 17, wherein the cover has an inner sidewall defining the opening, and at least one of the optical elements has a side surface extending substantially along and non-parallel to the inner sidewall.

20. The electronic device as claimed in claim 17, wherein the opening tapers toward the optical elements.
